(19) United States
(12) Patent Application Publication
(10) Pub. No.: US 2023/0253065 A1
(43) Pub. Date: Aug. 10, 2023

(54) RACK, AND MECHANISM FOR OPENING AND CLOSING FRONT PANEL

(71) Applicant: NEC Platforms, Ltd., Kawasaki-shi (JP)

(72) Inventor: Yohei IKEGAMI, Kanagawa (JP)

(73) Assignee: NEC Platforms, Ltd., Kawasaki-shi (JP)

(21) Appl. No.: 18/103,912

(22) Filed: Jan. 31, 2023

(30) Foreign Application Priority Data
Feb. 8, 2022 (JP) 2022-017587

(51) Int. Cl. G12B 9/04

(52) U.S. Cl. CPC G12B 9/04

(57) ABSTRACT

To provide a rack, a mechanism for opening and closing a front panel, and the like, to which the front panel is attached in an openable/closable manner, and capable to prevent the front panel from unexpectedly dropping off the rack. A rack configured to be mounted with a front panel in an openable/closable manner includes: a protrusion part provided in a flat plate shape on a frame near a front surface of the rack; and a screw hole formed in the protrusion part, wherein a screw is mounted to the screw hole in a state where a slit formed along one end portion of the front panel is inserted into the protrusion part.

This application is based upon and claims the benefit of priority from Japanese Patent Application No. 2022-17587, filed on Feb. 8, 2022, the disclosure of which is incorporated herein in its entirety by reference.

### TECHNICAL FIELD

The present invention relates to a rack, a mechanism for opening and closing a front panel, and the like, and particularly relates to a rack to which the front panel is attached in an openable/closable manner, a mechanism for opening and closing the front panel, and the like.

### BACKGROUND ART

Equipment including a front panel such as an openable/closable door is known. Such equipment is configured to include a rack and a front panel such as a door attached to the rack via a hinge unit in an openable/closable manner.

In a case of a door type where a front panel comes in a door, a hinge is generally used for attaching the front panel, but the hinge is costly. Therefore, it is difficult to inexpensively achieve the door type. In a case where there is not a sufficient space around an attachment component on the panel side for maintenance, it is necessary to remove the door for work in a wide space. When a hinge is used, the door cannot be easily removed, and maintenance is difficult. On the other hand, there is also a method of hooking a panel that is a component of a rack onto the rack side as in the door type, but there is a risk that the panel becomes imbalanced depending on the position of the center of gravity of the attachment component on the panel side and the panel falls on the foot at some moment, resulting in foot injury.

JP Sho62-190482 A relates to an opening and closing device that rotatably couples an exterior member such as a door to an equipment main body. JP Sho62-190482 A proposes engaging a hook-shaped curved portion provided at an end portion of an exterior member with an opening provided at an end portion of the equipment main body, and due to this, easily attaching the exterior member to the equipment main body with a small number of components.

The opening and closing device of JP Sho62-190482 A is expected to reduce the number of components and easily attach the exterior member to the equipment main body, but the exterior member only engages with a hook-shaped curved portion with respect to the equipment main body. Therefore, it is assumed that the exterior member can unexpectedly drop off the equipment main body.

### SUMMARY

In view of the above-described issues, an object of the present invention is to provide a rack, a mechanism for opening and closing a front panel, and the like, to which the front panel is attached in an openable/closable manner, and capable to prevent the front panel from unexpectedly dropping off the rack.

In order to achieve the above object, a rack according to the present invention is a rack configured to be mounted with a front panel in an openable/closable manner, and includes:

a protrusion part provided in a flat plate shape on a frame near a front surface of the rack; and

a screw hole formed in the protrusion part, wherein

a screw is mounted to the screw hole in a state where a slit formed along one end portion of the front panel is inserted into the protrusion part.

A mechanism for opening and closing a front panel according to the present invention includes:

a rack having a protrusion part provided in a flat plate shape on a frame near a front surface and a screw hole formed in the protrusion part; and

a front panel having a slit formed along one end portion, the front panel being attached to the rack in an openable/closable manner by the protrusion part being inserted into the slit, wherein

a screw is mounted to the screw hole in a state where the slit is inserted into the protrusion part.

According to the present invention, a front panel can be attached to a rack in an openable/closable manner, and the front panel can be prevented from unexpectedly dropping off the rack.

### BRIEF DESCRIPTION OF THE DRAWINGS

Exemplary features and advantages of the present invention will become apparent from the following detailed description when taken with the accompanying drawings in which:

FIG. 1 is a perspective view of a rack according to one example embodiment of the present invention in a state where a front panel is mounted and the front panel is closed;

FIG. 2 is a perspective view of the rack according to one example embodiment of the present invention;

FIG. 3 is an enlarged view of a portion A in FIG. 2;

FIG. 4 is a perspective view for illustrating a front panel mounted on the rack according to one example embodiment of the present invention;

FIG. 5 is a perspective view of the rack according to one example embodiment of the present invention in a state where the front panel is mounted and the front panel is opened; and

FIG. 6 is an enlarged view of a portion B in FIG. 5.

### EXAMPLE EMBODIMENT

A preferred example embodiment of the present invention will be described in detail with reference to the drawings.

### One Example Embodiment

A rack, and a mechanism for opening and closing a front panel according to one example embodiment of the present invention will be described.

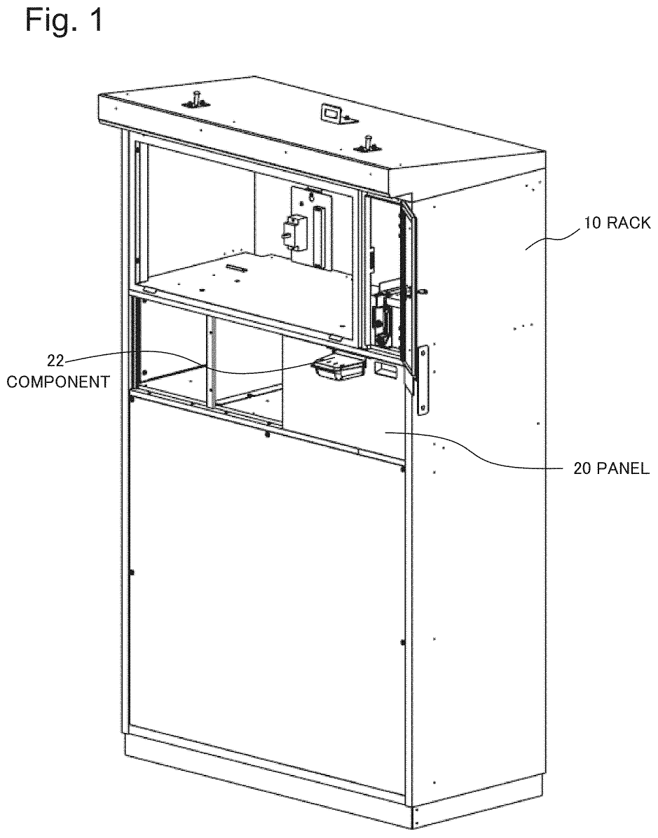

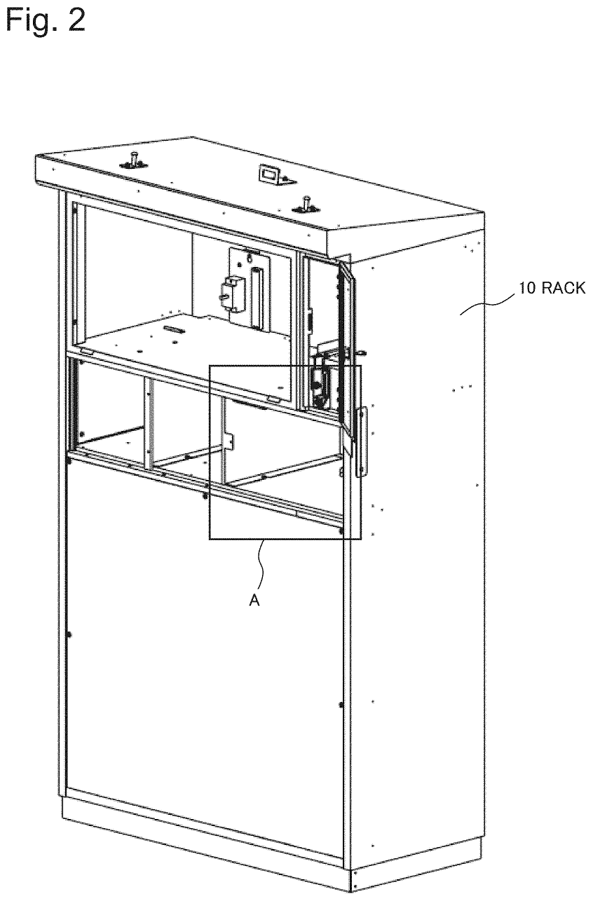

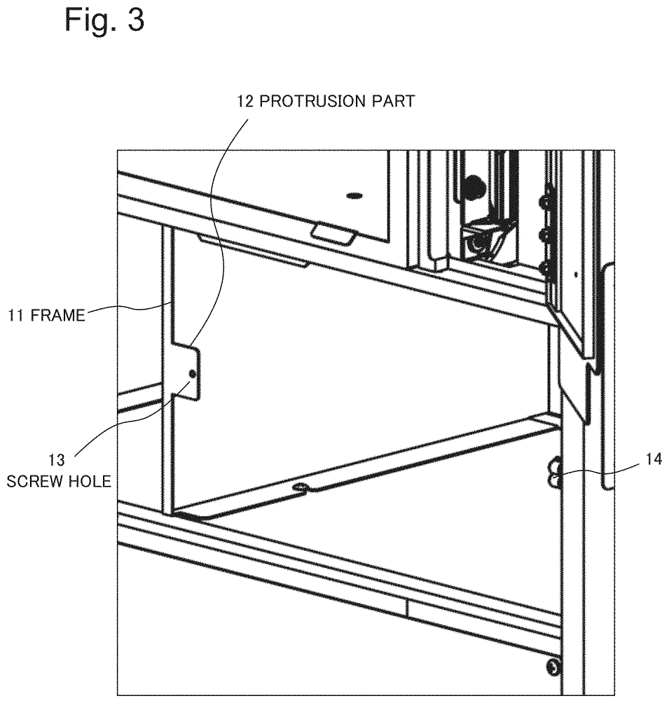

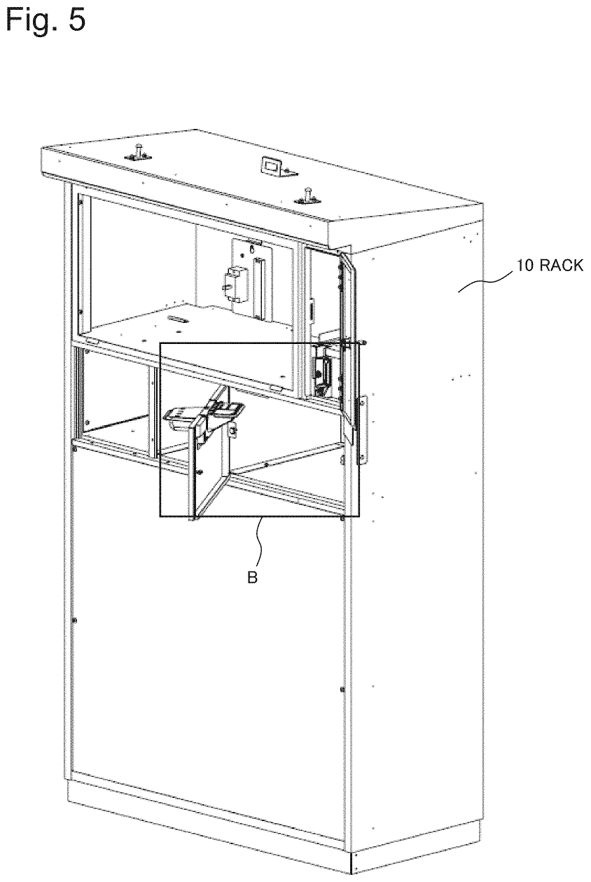

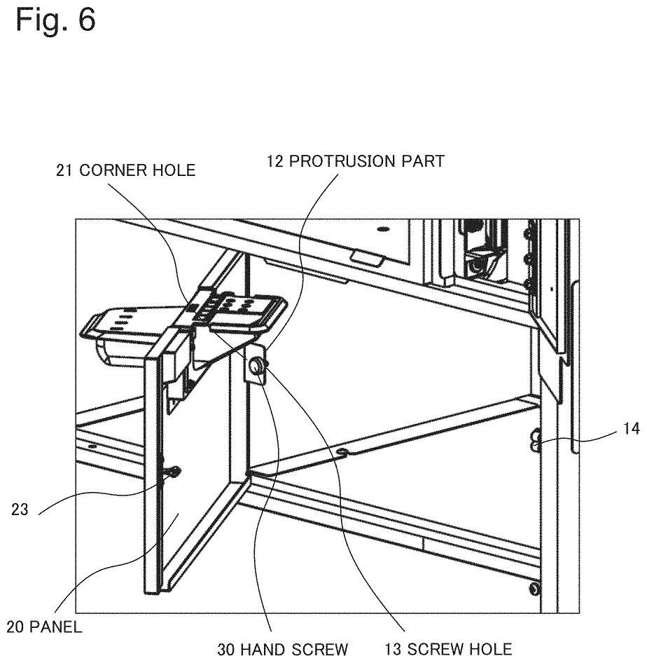

FIG. 1 is a perspective view of the rack according to one example embodiment of the present invention in a state where a front panel is mounted and the front panel is closed. FIG. 2 is a perspective view of the rack according to one example embodiment of the present invention. FIG. 3 is an enlarged view of the portion A in FIG. 2. FIG. 5 is a perspective view of the rack according to one example embodiment of the present invention in a state where the front panel is mounted and the front panel is opened. FIG. 6 is an enlarged view of the portion B in FIG. 5.

The rack according to one example embodiment of the present invention is a rack 10 mounted with a front panel in an openable/closable manner. As illustrated in FIG. 3, the rack 10 according to one example embodiment of the present invention includes a flat plate-shaped protrusion part 12 provided on a frame 11 near a front surface, the flat plate-shaped protrusion part 12 formed with a screw hole 13. The longitudinal direction of the flat plate-shaped protrusion part 12 is arranged parallel to the vertical direction. In other words, the longitudinal direction of the flat plate-shaped protrusion part 12 is arranged perpendicular to an installation surface of the rack 10.

Here, “parallel to the vertical direction” and “perpendicular to the ground contact surface” include manufacturing errors of about 0° to 5°, for example.

The rack 10 according to one example embodiment of the present invention includes a hand screw 30 as an example of a screw mounted in the screw hole 13. The hand screw 30 is screwed and mounted to the screw hole 13 by an operator or the like of the rack 10 in a state where a slit of the front panel is inserted into the flat plate-shaped protrusion part 12 (see FIG. 6).

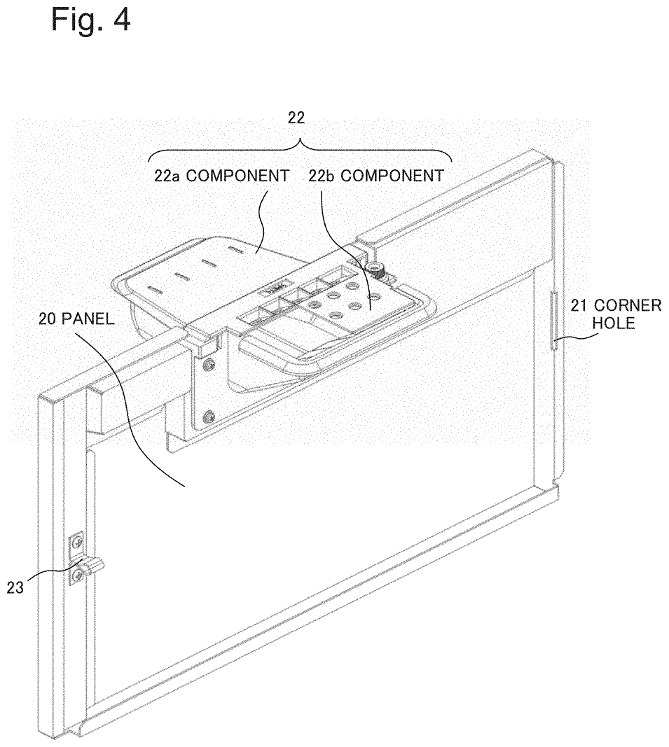

Next, the front panel mounted in an openable/closable manner on the rack 10 according to the present example embodiment will be described. FIG. 4 is a perspective view for illustrating the front panel mounted on the rack according to one example embodiment of the present invention. A panel 20 as an example of a front panel includes a corner hole 21 as an example of a slit formed along its one end portion, an engagement metal fitting 23 as an example of a fixing portion, and a component 22.

The corner hole 21, the engagement metal fitting 23, and the component 22 are formed in a panel main body of the panel 20, and the corner hole 21 is a slit formed along a bent portion of an end portion of the panel main body. The component 22 includes a component 22a located on the front surface side of the panel 20 and a component 22b located on the back surface side of the panel 20 with the panel main body as the center. FIG. 4 illustrates a perspective view when a main surface of the panel 20 is arranged parallel to the vertical direction, and in this state, the component 22 (22a and 22b) is arranged around an upper end of the panel main body.

The engagement metal fitting 23 is an Ω-shaped metal fitting, is arranged at the other end portion different from the one end portion where the corner hole 21 is formed, and constitutes a part of a fixing portion that locks the panel 20 in a state where the panel is closed. As illustrated in FIGS. 3 and 6, the rack 10 is provided with a reception unit 14 that engages with the engagement metal fitting 23 of the panel 20 in a state where the panel 20 is closed and locks the panel 20. The reception unit 14 illustrated in FIGS. 3 and 6 is an example of the reception unit 14 that is commonly called a roller catch and includes a roller unit.

### Description of Operation

Next, attachment of the front panel to the rack according to the present example embodiment and opening or closing operation of the attached front panel will be described as operation.

The panel 20 illustrated in FIG. 4 is attached to the rack 10 illustrated in FIGS. 2 and 3. At this time, the corner hole 21 of the panel 20 is inserted into the flat plate-shaped protrusion part 12 of the frame 11 of the rack 10 such that the corner hole 21 of the panel 20 reaches near a base of the flat plate-shaped protrusion part 12. In the case of the rack 10 according to the present example embodiment, the longitudinal direction of the flat plate-shaped protrusion part 12 is arranged parallel to the vertical direction. In other words, the longitudinal direction of the flat plate-shaped protrusion part 12 is arranged perpendicular to the installation surface of the rack 10. By the corner hole 21 of the panel 20 being inserted into the flat plate-shaped protrusion part 12 of this arrangement, an inner surface at upper end part of the corner hole 21 of the panel 20 comes into contact with an outer surface at upper end part of the flat plate-shaped protrusion part 12, and the weight of the panel 20 is supported by the flat plate-shaped protrusion part 12 centered on the upper end part of the flat plate-shaped protrusion part 12. In this state, the panel 20 is hooked on the flat plate-shaped protrusion part 12 of the rack 10, and roughly, the panel 20 is in a state of being attached to the rack 10 so as not to drop.

In the rack 10 according to the present example embodiment, the hand screw 30 is further screwed into the screw hole 13 of the flat plate-shaped protrusion part 12 in a state where the corner hole 21 of the panel 20 is inserted into the flat plate-shaped protrusion part 12 (See FIGS. 5 and 6). The action of the hand screw 30 screwed into the screw hole 13 can prevent the panel 20 from dropping off the rack 10. For example, even when the panel 20 is opened or closed, the action of the hand screw 30 screwed into the screw hole 13 can prevent the panel 20 from dropping off the rack 10.

Thus, the panel 20 can be attached to the rack 10 in an openable/closable manner. When the engagement metal fitting 23 of the panel 20 is engaged with the reception unit 14 of the rack 10 in the state where the panel 20 is closed, the panel 20 is locked in a closed state. As illustrated in FIG. 4, among the components 22 of the panel 20, the component 22a as an example of a first component is arranged on the front surface side of the panel 20, and the component 22b as an example of a second component is arranged on the back surface side of the panel 20. The component 22a is exposed to the front surface of the panel 20 even in a state where the panel 20 is closed. The component 22b is hidden by the panel 20 in a state where the panel 20 is closed. In the rack 10 according to the present example embodiment, the component 22a among the components 22 of the panel 20 is exposed to the front surface of the panel 20, and the operator of the rack 10 can access and operate the component 22a even in a state where the panel 20 is closed.

### Advantageous Effects of Example Embodiment

In the rack 10 of the present example embodiment, the rack 10 is provided with the protrusion part 12, and the corner hole 21 on the panel 20 side is passed through the protrusion part 12. After the corner hole 21 of the panel 20 is passed through the protrusion part 12, the hand screw 30 is tightened to the protrusion part 12. Due to this, the corner hole 21 of the panel 20 and the protrusion part 12 of the rack 10 constitute a door, and the hand screw 30 prevents dropping of the panel 20 and injury caused by dropping. Removal of the hand screw 30 enables the panel 20 to be removed, and work to be performed in a wide space with respect to the panel 20.

That is, according to the rack 10 of the present example embodiment, the panel as an example of a front panel can be easily attached in an openable/closable manner with a small number of components. In a state where the corner hole 21 of the panel 20 as an example of a slit formed along one end portion of the front panel is inserted into the flat plate-shaped protrusion part 12, the hand screw 30 as an example of a screw is attached to the screw hole 13. The action of the hand screw 30 screwed into the screw hole 13 can prevent the panel 20 from unexpectedly dropping off the rack 10. For example, even when the panel 20 is opened or closed, the action of the hand screw 30 screwed into the screw hole 13 can prevent the panel 20 from unexpectedly dropping off the rack 10.

This makes it possible to solve the issue that the panel 20 becomes imbalanced depending on the position of the center of gravity of the attachment component on the panel 20 side, and the panel 20 drops and falls at some moment. In the case of the configuration in which the component 22 (22a and 22b) of the panel 20 is arranged around the upper end of the panel main body as in the above-described example embodiment, the imbalance due to the position of the center of gravity of the attachment component on the panel 20 side is likely to emerge. Adoption of the above-described configuration makes it possible to solve the issue that the panel 20 becomes imbalanced, and the panel 20 drops and falls at some moment.

In the rack 10 of the present example embodiment, since it is possible to easily remove the panel 20 from the rack 10 as necessary, it is easy to maintain an attachment component on the panel side such as the component 22 in another wide space.

In the rack 10 of the present example embodiment, a hinge unit that can open or close the panel 20 is configured by a state in which the corner hole 21 of the panel 20 as an example of a slit formed along one end portion of the front panel is inserted into the flat plate-shaped protrusion part 12. In the rack 10 of the present example embodiment, the flat plate-shaped protrusion part 12 is formed in the frame 11 of the rack 10, and the corner hole 21 as an example of a slit is formed in the panel 20 as an example of a front panel. The panel 20 is attached to and detached from the rack 10 as necessary, and due to the corner hole 21 formed on the panel 20 side, the panel 20 side has a structure or a outer shape with less unevenness and protrusion shapes. This facilitates handling of the panel 20 for the operator or the like of the rack 10, and makes it possible to reduce an accidental possibility that the protrusion shape on the panel 20 side is hooked on something or something is damaged by the protrusion shape on the panel 20 side.

In a case where a rack is placed, for example, near a wall or near a column, the panel to which a component requiring maintenance is attached has an issue that the space for maintenance of the component is very narrow. In a case where the workspace for component maintenance is narrow, the worker has to perform maintenance in an improper posture, and can damage a component such as plastic in particular. In order to avoid maintenance work in a narrow space, it is desirable that a panel to which a component requiring maintenance is attached be attachable/detachable. On the other hand, the attachable/detachable panel causes the panel to fall at some moment and damages a component or a panel, or causes an injury due to the panel dropping. Such issue can be solved by adopting the rack 10 having the above-described configuration.

Although the preferred example embodiment of the present invention has been described above, the present invention is not limited to this. The fixing portion that locks the front panel in a state where the front panel is closed is not limited to the fixing mechanism commonly called a roller catch as in the above-described example embodiment, and a magnet catch, a ball catch, or other commonly used fixing mechanisms may be used. The elements constituting the fixing portion may be interchanged and arranged as, for example, the engagement metal fitting 23 is arranged on the rack 10 side and the reception unit 14 is arranged on the panel 20 side. Various modifications are possible within the scope of the invention described in the claims, and it goes without saying that they are also included in the scope of the present invention.

A part or the entirety of the above example embodiment can be described as the following supplementary notes, but are not limited to the following.

(Supplementary Note 1) A rack configured to be mounted with a front panel in an openable/closable manner, the rack including:

a protrusion part provided in a flat plate shape on a frame near a front surface of the rack; and

a screw hole formed in the protrusion part, in which

a screw is mounted to the screw hole in a state where a slit formed along one end portion of the front panel is inserted into the protrusion part.

(Supplementary Note 2) The rack according to Supplementary Note 1, in which

a longitudinal direction of the protrusion part is arranged parallel to a vertical direction.

(Supplementary Note 3) The rack according to Supplementary Note 1 or 2, in which

a hinge unit that can open or close the front panel is formed by the slit being inserted to near a base of the protrusion part.

(Supplementary Note 4) The rack according to any one of Supplementary Notes 1 to 3, in which

the front panel is provided with a fixing portion that is provided at other end portion different from the one end portion and locks the front panel in a state where the front panel is closed.

(Supplementary Note 5) A mechanism for opening and closing a front panel, the mechanism including:

a rack having a protrusion part provided in a flat plate shape on a frame near a front surface and a screw hole formed in the protrusion part; and

a front panel having a slit formed along one end portion, the front panel being attached to the rack in an openable/closable manner by the protrusion part being inserted into the slit, in which a screw is mounted to the screw hole in a state where the slit is inserted into the protrusion part.

(Supplementary Note 6) The mechanism for opening and closing a front panel according to Supplementary Note 5, in which

a longitudinal direction of the protrusion part is arranged parallel to a vertical direction.

(Supplementary Note 7) The mechanism for opening and closing a front panel according to Supplementary Note 5 or 6, in which

a hinge unit that can open or close the front panel is formed by the slit being inserted to near a base of the protrusion part.

(Supplementary Note 8) The mechanism for opening and closing a front panel according to any one of Supplementary Notes 5 to 7, in which

the front panel is provided with a fixing portion that is provided at the other end portion different from the one end portion and locks the front panel in a state where the front panel is closed.

(Supplementary Note 9) The mechanism for opening and closing a front panel according to any one of Supplementary Notes 5 to 8, in which

the front panel includes a first component exposed to a front surface of the front panel in a state where the front panel is closed.

(Supplementary Note 10) The mechanism for opening and closing a front panel according to any one of Supplementary Notes 5 to 9, in which

the front panel includes a second component hidden by the front panel in a state where the front panel is closed.

Further, it is noted that the inventor's intent is to retain all equivalents of the claimed invention even if the claims are amended during prosecution.

1. A rack configured to be mounted with a front panel in an openable/closable manner, the rack comprising:
a protrusion part provided in a flat plate shape on a frame near a front surface of the rack; and
a screw hole formed in the protrusion part, wherein
a screw is mounted to the screw hole in a state where a slit formed along one end portion of the front panel is inserted into the protrusion part.

2. The rack according to claim 1, wherein
a longitudinal direction of the protrusion part is arranged parallel to a vertical direction.

3. The rack according to claim 1, wherein a hinge unit that can open or close the front panel is formed by the slit being inserted to near a base of the protrusion part.

4. The rack according to claim 1, wherein
the front panel is provided with a fixing portion that is provided at other end portion different from the one end portion and locks the front panel in a state where the front panel is closed.

5. A mechanism for opening and closing a front panel, the mechanism comprising:
a rack having a protrusion part provided in a flat plate shape on a frame near a front surface and a screw hole formed in the protrusion part; and
a front panel having a slit formed along one end portion, the front panel being attached to the rack in an openable/closable manner by the protrusion part being inserted into the slit, wherein
a screw is mounted to the screw hole in a state where the slit is inserted into the protrusion part.

6. The mechanism for opening and closing a front panel according to claim 5, wherein
a longitudinal direction of the protrusion part is arranged parallel to a vertical direction.

7. The mechanism for opening and closing a front panel according to claim 5, wherein
a hinge unit that can open or close the front panel is formed by the slit being inserted to near a base of the protrusion part.

8. The mechanism for opening and closing a front panel according to claim 5, wherein
the front panel is provided with a fixing portion that is provided at other end portion different from the one end portion and locks the front panel in a state where the front panel is closed.

9. The mechanism for opening and closing a front panel according to claim 5, wherein
the front panel includes a first component exposed to a front surface of the front panel in a state where the front panel is closed.

10. The mechanism for opening and closing a front panel according to claim 5, wherein
the front panel includes a second component hidden by the front panel in a state where the front panel is closed.

11. The mechanism for opening and closing a front panel according to claim 6, wherein
a hinge unit that can open or close the front panel is formed by the slit being inserted to near a base of the protrusion part.

12. The mechanism for opening and closing a front panel according to claim 6, wherein
the front panel is provided with a fixing portion that is provided at other end portion different from the one end portion and locks the front panel in a state where the front panel is closed.

13. The mechanism for opening and closing a front panel according to claim 6, wherein
the front panel includes a first component exposed to a front surface of the front panel in a state where the front panel is closed.

14. The mechanism for opening and closing a front panel according to claim 6, wherein
the front panel includes a second component hidden by the front panel in a state where the front panel is closed.

15. The mechanism for opening and closing a front panel according to claim 7, wherein
the front panel is provided with a fixing portion that is provided at other end portion different from the one end portion and locks the front panel in a state where the front panel is closed.

16. The mechanism for opening and closing a front panel according to claim 7, wherein
the front panel includes a first component exposed to a front surface of the front panel in a state where the front panel is closed.

17. The mechanism for opening and closing a front panel according to claim 7, wherein
the front panel includes a second component hidden by the front panel in a state where the front panel is closed.
